(19) United States
(12) Patent Application Publication
(10) Pub. No.: US 2020/0125150 A1
(43) Pub. Date: Apr. 23, 2020

(54) POWER QUALITY DETECTING SYSTEM AND POWER QUALITY DETECTING MODULE

(71) Applicant: RayMX Microelectronics, Corp., Anhui province (CN)

(72) Inventors: Yen-Chung CHEN, Zhubei City (TW); Wen-Hsin CHANG, Yuanlin City (TW); Tzu-Yu CHAO, Taichung City (TW); Li-Chun HUANG, Douliu City (TW)

(21) Appl. No.: 16/452,775

(22) Filed: Jun. 26, 2019

(30) Foreign Application Priority Data
Oct. 17, 2018 (TW) 107136539

(51) Int. Cl. G06F 1/26; G01R 22/10; G01R 21/133

(52) U.S. Cl. CPC G06F 1/26; G01R 21/133; G01R 22/10

(57) ABSTRACT

A power quality detecting system includes a power module, a storage device, and a power quality detecting module. The power module receives an external power source. The power module converts the external power source into a first internal voltage. The power quality detecting module is electrically connected to the power module and the storage device. The storage device is electrically connected to the power module for receiving the first internal voltage through the power quality detecting module. The power quality detecting module determines whether a first alarm signal is transmitted according to a quality parameter of the first internal voltage.

### FIELD OF THE DISCLOSURE

The present disclosure relates to a power quality detecting system and a power quality detecting module, and more particularly to a power quality detecting system and a power quality detecting module that is disposed between the power module and the storage device.

### BACKGROUND OF THE DISCLOSURE

The storage device, especially a memory card, a solid state disk (SSD), requires a stable voltage for operation. If the AC voltage of a power environment changes too much and the design of the power module in storage device is poor, the stable voltage cannot be provided to the storage device. If the voltage supplied to the storage device is not stable (e.g., too high or too low or the variability is too large), the storage device may malfunction, produce read and write errors, or even be damaged.

Therefore, it has become an important issue to provide a power quality detection system and module for detecting power quality.

### SUMMARY OF THE DISCLOSURE

In response to the above-referenced technical inadequacies, the present disclosure provides a power quality detecting system.

In one aspect, the present disclosure provides a power quality detecting system, comprising: a power module to receive an external power source and to convert the external power source into a first internal voltage; a storage device; and a power quality detecting module coupled to the power module and the storage device, wherein the storage device receives the first internal voltage through the power quality detecting module; wherein the power quality detecting module determines a quality parameter of the first internal voltage according to a waveform of the first internal voltage, and determines whether a first alarm signal is generated according to the quality parameter of the first internal voltage.

In certain embodiments, the present disclosure provides a power quality detecting method, comprising: receiving, by a power module, an external power source; converting, by the power module, the external power source into a first internal voltage; providing the first internal voltage to a storage device through a power quality detecting module; determining, by the power quality detecting module, a quality parameter of the first internal voltage according to a waveform of the first internal voltage; and generating, by the power quality detecting module, a detecting result according to the quality parameter of the first internal voltage.

Therefore, the present invention uses the power quality detecting system to detect the first internal voltage transmitted to the storage device for determining the power quality of the first internal voltage, and effectively determines the operating environment of the storage device. Furthermore, a solution can be quickly provided when the voltage is unstable.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic diagram of a power quality detecting system according to the embodiment of the present disclosure.

FIG. 2 is another schematic diagram of a power quality detecting system according to the embodiment of the present disclosure.

FIG. 3 is a schematic diagram that the power quality detecting system of the present disclosure detects a first internal voltage.

FIG. 4 is another schematic diagram that the power quality detecting system of the present disclosure detects a first internal voltage.

FIG. 5 is another schematic diagram that the power quality detecting system of the present disclosure detects a first internal voltage.

FIG. 6 is a schematic diagram of a power quality detecting module according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

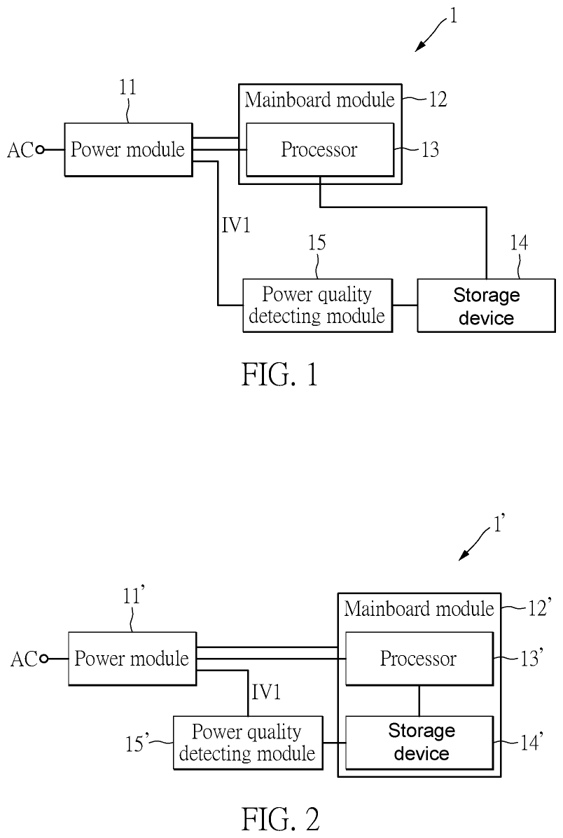

Referring to FIG. 1 and FIG. 2, FIG. 1 is a schematic diagram of a power quality detecting system according to the embodiment of the present disclosure, while FIG. 2 is another schematic diagram of a power quality detecting system according to the embodiment of the present disclosure.

The power quality detecting system 1 includes a power module 11, a mainboard module 12, a processor 13, a storage device 14, and a power quality detecting module 15.

In an embodiment, the power supplier 11 receives an external power AC and converts the external power AC to a first internal voltage IV1.

The power quality detecting module 15 is electrically connected to the power module 11 and the storage device 14. The storage device 14 is electrically connected to the power module 11 for receiving the first internal voltage IV1.

The mainboard module 12 is electrically connected to the power module 11. The processor 13 is mounted on the mainboard module 12. The processor 13 is electrically connected to the power module 11, and the storage device 14.

In the embodiment, a computer system (not shown) includes the power module 11, the mainboard module 12, the processor 13, and the storage device 14.

In the embodiment, the computer system (not shown) further includes an operation system (OS) executed by the power module 11, the mainboard module 12, the processor 13, and the storage device 14.

In this embodiment, the storage device 14 is disposed on the mainboard module 12. For example, the storage device 14 is directly disposed on the mainboard module 12 through a Peripheral Component Interconnect Express interface (PCIe). The storage device 14 can also be separate from the mainboard module 12. For example, the storage device 14 is electrically connected to the motherboard module through a transmission line and a sequence of Serial Advanced Technology Attachment interface (SATA).

As shown in FIG. 2, the power quality detecting system 1′ of FIG. 2 includes a power module 11′, a mainboard module 12′, a processor 13′, a storage device 14′, and a power quality detecting module 15′. The power quality detecting system 1 of FIG. 1 is different from the power quality detection system 1′ of FIG. 2 in that the storage device 14 of FIG. 1 is not disposed on the mainboard module 12, while the storage device 14′ of FIG. 2 is disposed on the mainboard module 12′.

In the embodiment, the storage device 14 is a solid-state disk (SSD) or memory card.

In the embodiment, the power quality detecting module 15 determines whether an alarm signal is transmitted based on a quality parameter of the first internal voltage IV1. In the embodiment, large fluctuation of the external power AC or poor design of the power supply module 11 or poor component in the power module 11 may cause the first internal voltage IV1 to experience large voltage variation. Therefore, in the embodiment, the voltage variation of the first internal voltage IV1 can be several volts.

The quality parameter of the first internal voltage IV1 is determined based on a first number of times that the first internal voltage IV1 is greater than a first high voltage threshold HT1 within a predetermined time T, a second number of times that the first internal voltage IV1 is less than a first low voltage threshold LT1 within a predetermined time T, or a combination of the first number of times and a second number of times.

In other words, when the first number of times that the first internal voltage IV1 is greater than the first high voltage threshold HT1 within the predetermined time T is greater than a first predetermined number of times, the quality parameter of the first internal voltage IV1 is unqualified. Therefore, the power quality detecting module 15 transmits a first alarm signal.

When the second number of times that the first internal voltage IV1 is less than the first low voltage threshold LT1 within the predetermined time T is greater than a second predetermined number of times, the quality parameter of the first internal voltage IV1 is also unqualified. Therefore, the power quality detecting module 15 also transmits a first alarm signal.

Moreover, when the first number of times that the first internal voltage IV1 is greater than the first high voltage threshold HT1 within the predetermined time T is greater than a third predetermined number of times, and the second number of times that the first internal voltage IV1 is less than the first low voltage threshold LT1 within the predetermined time T is greater than a fourth predetermined number of times, the power quality detecting module 15 also transmits the first alarm signal.

In the embodiment, the first high voltage threshold HT1 and the first low voltage threshold LT1 are determined based on a voltage that causes operation errors, read/write errors, malfunction, or hardware damage in the storage device 14, but is not limited in the present disclosure.

In the embodiment, the first predetermined number of times, the second predetermined number of times, the third predetermined number of times, and the fourth predetermined number of times can be designed and adjusted based on actual requirements, and is not limited in the present disclosure. In addition, the predetermined time T can also be adjusted based on actual requirements, and is not limited in the present disclosure.

In the embodiment, the power quality detecting module 15 provides the alarm signal to the processor 13 or an operating system (not shown) executed in the processor 13 of the computer system (not shown). The processor 13 or the operating system (not shown) will record according to the alarm signal or remind the user that the current power quality is poor.

In the embodiment, when the first internal voltage IV1 is greater than a second high voltage threshold HT2, the power quality detecting module 15 transmits a second alarm signal. Similarly, when the first internal voltage IV1 is lower than a second low voltage threshold LT2, the power quality detecting module 15 also transmits a second alarm signal.

In the embodiment, the second alarm signal is used for notifying the processor 13 or an operating system (not shown). In addition, the second high voltage threshold HT2 is greater than the first high voltage threshold HT1. The second low voltage threshold LT2 is less than the first low voltage threshold LT1.

In the embodiment, the second high voltage threshold HT2 and the second low voltage threshold LT2 are determined according to the voltage that may be damaged in the storage device 14. In other words, as long as the first internal voltage IV1 exceeds the second high voltage threshold HT2 or is lower than the second low voltage threshold LT2, the storage device 14 may be damaged or inoperative.

Referring to FIG. 1 and FIG. 2, the storage device 14 in FIG. 1 is not disposed on the mainboard module 12, while the storage device 14 in FIG. 2 is disposed on the mainboard module 12.

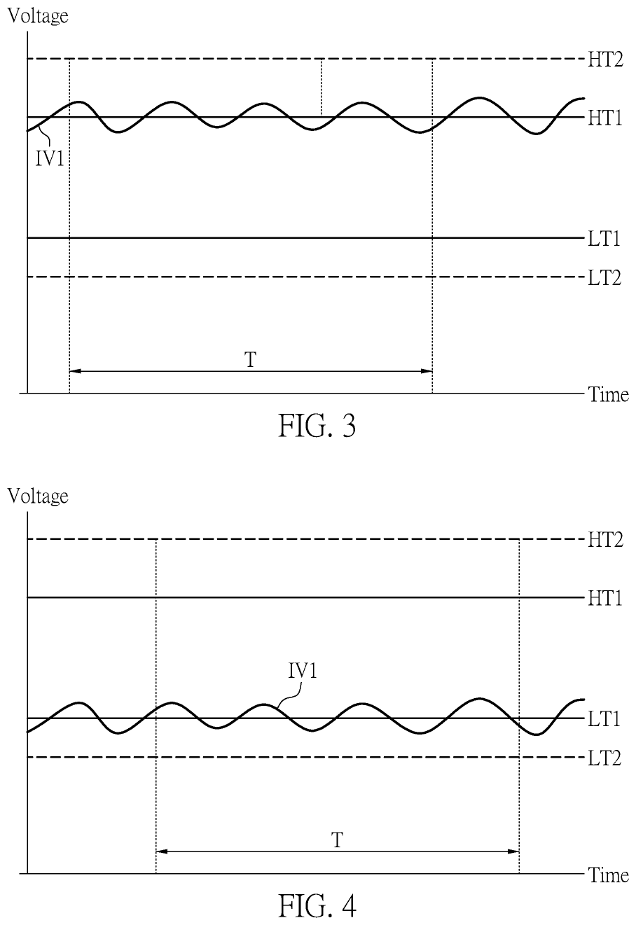

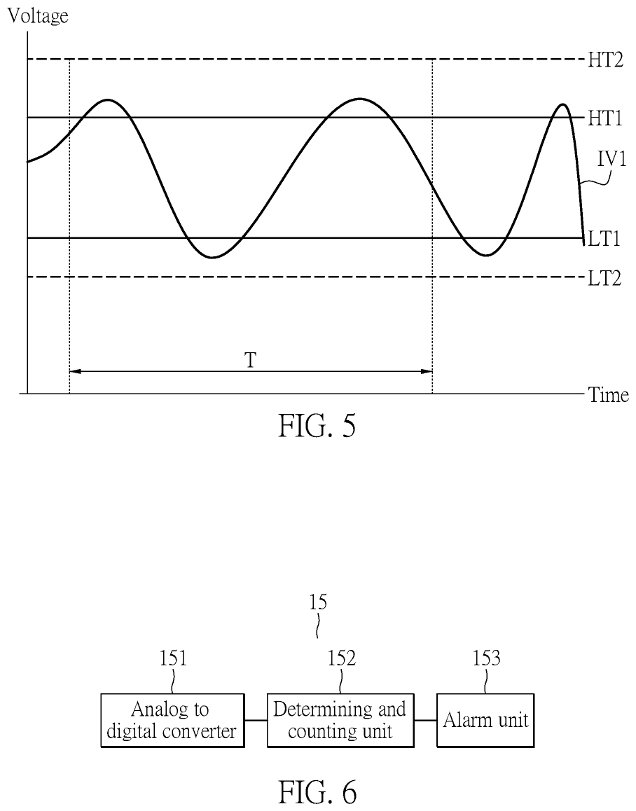

Referring to FIG. 3 to FIG. 5, FIG. 3 is a schematic diagram showing the power quality detecting system of the present disclosure detecting a first internal voltage. FIG. 4 is another schematic diagram showing the power quality detecting system of the present disclosure detecting a first internal voltage. FIG. 5 is another schematic diagram showing the power quality detecting system of the present disclosure detecting a first internal voltage.

Referring to FIG. 3, the voltage curve of the first internal voltage IV1 in FIG. 3 is greater than the first low voltage threshold LT1, so the storage device 14 receiving the first internal voltage IV1 in FIG. 3 can operate. However, since the peak value of the first internal voltage IV1 is greater than the first high voltage threshold HT1, the storage device 14 may be damaged.

In the embodiment, the power quality detecting module 15 detects whether the number of times that the first internal voltage IV1 is greater than the first high voltage threshold HT1 within the predetermined time T is greater than the first predetermined number of times. In the embodiment, the first predetermined number of times is five. However, in FIG. 3, the number of times that the first internal voltage IV1 is greater than the first high voltage threshold HT1 is four. Therefore, the power quality detecting module 15 does not transmit the first alarm signal.

Referring to FIG. 4, the voltage curve of the first internal voltage IV1 in FIG. 4 is smaller than the first high voltage threshold HT1, so that the storage device 14 receiving the first internal voltage IV1 in FIG. 4 is not damaged by the excessive voltage. However, since the minimum value of the first internal voltage IV1 is less than the first low voltage threshold LT1, the storage device 14 may malfunction or produce a read/write error.

In this embodiment, the power quality detecting module 15 detects whether the number of times that the first internal voltage IV1 is less than the first low voltage threshold LT1 within the predetermined time T is greater than a second predetermined number of times. In the present embodiment, the second predetermined number of times is two. In FIG. 4, the number of times that the first internal voltage IV1 is less than the first low voltage threshold HT1 within the predetermined time T is four, and therefore, the power quality detecting module 15 transmits the first alarm signal.

Referring to FIG. 5, the voltage curve of the first internal voltage IV1 in FIG. 5 is between the second high voltage threshold HT2 and the second low voltage threshold LT2. However, a portion of the first internal voltage IV1 in FIG. 5 is greater than the first high voltage threshold HT1, and a portion of the first internal voltage IV1 is less than the first low voltage threshold LT1. Therefore, the storage device 14 receiving the first internal voltage IV1 in FIG. 5 is in risk of damage due to the excessive voltage, or is in risk of malfunction or producing a read/write error due to the low voltage.

In the embodiment, the power quality detecting module 15 detects whether the number of times that the first internal voltage IV1 is greater than the first high voltage threshold HT1 within the predetermined time T is greater than a third predetermined number of times, and the number of times that the first internal voltage IV1 is less than the first low voltage threshold in time T within the predetermined time is greater than the fourth predetermined number of times. In the present embodiment, the third predetermined number of times and the fourth predetermined number of times are one.

In FIG. 5, the number of times that the first internal voltage IV1 is greater than the first high voltage threshold HT1 and less than the first low voltage threshold LT1 within the predetermined time T is respectively two times and one time, respectively. Therefore, the power quality detecting module 15 would transmit the alarm signal.

Referring to FIG. 6, FIG. 6 is a schematic diagram of a power quality detecting module according to the embodiment of the present disclosure.

In the embodiment, the power quality detecting module 15 includes an analog to digital convertor 151, a determining and counting unit 152, and an alarm unit 153.

The analog to digital converter 151 is used for converting the first internal voltage IV1 from analog form to digital form. The determining and counting unit 152 is electrically connected to the analog to digital converter 151 for determining the voltage level of the first internal voltage IV1 and the number of times for the quality parameter of the first internal voltage IV1. The determining and counting unit 152 generates a determined result according to the quality parameter.

In other words, the determining and counting unit 152 determines whether the first internal voltage IV1 in digital form is greater than the first high voltage threshold HT1 or lower than the first low voltage threshold for determining the quality parameter of the first internal voltage IV1.

In this embodiment, the alarm unit 153 is electrically connected to the determining and counting unit 152, and determines, by the determining and counting unit 152, whether a first alarm signal or a second alarm signal is transmitted according to the determined result of the quality parameter of the first internal voltage IV1.

For example, in the embodiment where storage blocks in the storage device 14 is realized with Quad-level cells (QLC) chips, the storage block in the storage device may use a one-bit-per-cell (1bpc) programming mode, a two-bit-per-cell (2bpc) programming mode, a three-bit-per-cell (3bpc) programming mode, or the four-bit-per-cell (4bpc) programming mode to program data.

Therefore, when the power quality detecting module 15 determines that the quality of the voltage IV1 is not good (for example, sending the first warning signal or the second warning signal), the programming mode of the storage device 14 is changed such that it is not easy to make an erroneous operation. For example, the control circuit in SSD selects one of a plurality of programming modes according to the quality control signal or the warning signal to program the programmed data into a first storage block of the flash memory. The above method can improve data reliability.

In addition, the power quality detecting module 15 can record the waveform type of the internal voltage IV1. For example, a controller in storage device 14 determine that the waveform patterns in FIG. 3 and FIG. 4 is the same (the frequency is substantially fixed); and determine that the waveforms in FIG. 3 (or FIG. 4) and FIG. 5 are different waveforms patterns due to the frequency of the waveform is variable. When the controller in storage device 14 finds that the waveform of the internal voltage IV1 appears in different waveform patterns, the controller in storage device 14 may determine that the component in the power module 11 is defective and another warning signal is generated because the frequency of the external power AC is fixed.

In conclusion, the present invention uses the power quality detecting system to detect the first internal voltage transmitted to the storage device for determining the power quality of the first internal voltage, and effectively determines the operating environment of the storage device. Furthermore, a solution can be quickly provided when the voltage is unstable.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power quality detecting system, comprising:
a power module to receive an external power source and to convert the external power source into a first internal voltage;
a storage device; and
a power quality detecting module coupled to the power module and the storage device, wherein the storage device receives the first internal voltage through the power quality detecting module;
wherein the power quality detecting module determines a quality parameter of the first internal voltage according to a waveform of the first internal voltage, and determines whether a first alarm signal is generated according to the quality parameter of the first internal voltage.

2. The power quality detecting system of claim 1, wherein the quality parameter is determined based on a first number of times that the first internal voltage is greater than a first high voltage threshold in a predetermined time, a second number of times that the first internal voltage is less than a first low voltage threshold in the predetermined time, or a combination of the first number of times and the second number of times.

3. The power quality detecting system of claim 2, wherein when the first number of times is greater than a first predetermined number and/or the second number of times is greater than a second predetermined number, the power quality detecting module transmits a first alarm signal.

4. The power quality detecting system of claim 2, wherein when the first internal voltage is greater than a second high voltage threshold and/or the first internal voltage is less than a second low voltage threshold, the power quality detecting module transmits a second alarm signal.

5. The power quality detecting system of claim 1, further comprising:
a mainboard module, electrically connected to the power module; and
a processor configured on the mainboard module, the processor coupled to the storage device via the mainboard module;
wherein the first alarm signal is provided to an operation system executed in the processor.

6. The power quality detecting system of claim 1, the power quality detecting module determining a waveform pattern of the first internal voltage from a plurality of waveform patterns to generate a detecting result which indicates status of the power module.

7. The power quality detecting system of claim 6, wherein the detecting result indicates whether a frequency of the first internal voltage is substantially changed.

8. The power quality detecting system of claim 1, the power quality detecting module detecting a waveform pattern of the first internal voltage to generate a detecting result, and a controller of the storage device perform one of a plurality of programming modes to program data according to the detecting result.

9. The power quality detecting system of claim 8, wherein the plurality of programming modes comprises a one-bit-per-cell (1 bpc) programming mode and a two-bit-per-cell (2bpc) programming mode.

10. The power quality detecting system of claim 1, the power quality detecting module comprising:
an analog to digital converter (ADC) to convert an analog voltages of the first internal voltage into digital form;
a determining and counting unit, coupled to the ADC, to determine a voltage level and the quality parameter of the first internal voltage, and generating a detecting result based on the quality parameter.

11. A power quality detecting method, comprising:
receiving, by a power module, an external power source;
converting, by the power module, the external power source into a first internal voltage;
providing the first internal voltage to a storage device through a power quality detecting module;
determining, by the power quality detecting module, a quality parameter of the first internal voltage according to a waveform of the first internal voltage; and
generating, by the power quality detecting module, a detecting result according to the quality parameter of the first internal voltage.

12. The method of claim 11, wherein the quality parameter is determined based on a first number of times that the first internal voltage is greater than a first high voltage threshold in a predetermined time, a second number of times that the first internal voltage is less than a first low voltage threshold in the predetermined time, or a combination of the first number of times and the second number of times.

13. The method of claim 12, further comprising:
generating a first alarm signal when the first number of times is greater than a first predetermined number and/or the second number of times is greater than a second predetermined number.

14. The method of claim 13, further comprising:
generating a second alarm signal when the first internal voltage is greater than a second high voltage threshold and/or the first internal voltage is less than a second low voltage threshold.

15. The method of claim 11, wherein the step of generating the detecting result further comprises:
determining a waveform pattern of the first internal voltage from a plurality of waveform patterns to generate the detecting result.

16. The method of claim 11, wherein the detecting result indicates whether a frequency of the first internal voltage is substantially changed.

17. The method of claim 16, wherein the detecting result indicates a status of the power module.

18. The method of claim 11, further comprising:
performing, by a controller of the storage device, one of a plurality of programming modes to program data in the storage device according to the detecting result.

19. The method of claim 18, wherein the plurality of programming modes comprises a one-bit-per-cell (1bpc) programming mode and a two-bit-per-cell (2bpc) programming mode.
